(19) United States
(12) Patent Application Publication
(10) Pub. No.: US 2025/0087981 A1
(43) Pub. Date: Mar. 13, 2025

(54) WIRING MEMBER ROUTING STRUCTURE

(71) Applicant: SUMITOMO WIRING SYSTEMS, LTD., Mie (JP)

(72) Inventors: Naofumi YAMATAKE, Mie (JP); Takahiro MURATA, Mie (JP)

(21) Appl. No.: 18/726,829

(22) PCT Filed: Dec. 23, 2022
(86) PCT No.: PCT/JP2022/047506

§ 371 Date: Jul. 5, 2024

(30) Foreign Application Priority Data
Jan. 12, 2022 (JP) 2022-002875

(51) Int. Cl. H02G 3/22; B60K 7/00; B60R 16/02; H05K 7/20

(52) U.S. Cl. CPC H02G 3/22; B60K 7/0007; B60R 16/0215; H05K 7/20854

(57) ABSTRACT

It is aimed to enhance a degree of freedom of a path of a wiring member to be connected to an inverter located on a wheel side. A wiring member routing structure includes an in-wheel motor unit including an in-wheel motor, an inverter to be connected to the in-wheel motor and a casing for accommodating the in-wheel motor and the inverter, and a wiring member for connecting the inverter and a vehicle body-side device. An end part to be connected to the inverter in the wiring member serves as a first fixed part, and a part of the wiring member to be fixed to a vehicle next to the end part serves as a second fixed part. The casing includes a wiring fixing portion, to which the second fixed part is fixed.

### TECHNICAL FIELD

The present disclosure relates to a wiring member routing structure.

### BACKGROUND

Patent Document 1 discloses a wiring device for supplying an electrical signal from a vehicle body to an in-wheel motor. In Patent Document 1, an end part of a wire is fixed to a connector part of the in-wheel motor. To reduce a load on the end part of the wire, a fixed part next to the end part of the wire is fixed near a king pin, which is a center of rotation at the time of changing a tire turning angle according to the rotation of a steering wheel.

### PRIOR ART DOCUMENT

### Patent Document

Patent Document 1: JP 2005-271909 A

### SUMMARY OF THE INVENTION

### Problems to be Solved

Direct-current power from a battery is converted into alternating-current power by an inverter and supplied to the in-wheel motor. This inverter may be reduced in size and arranged on a wheel side together with the in-wheel motor. It is desired to enhance a degree of freedom of a path of a wiring member to be connected to the inverter located on the wheel side.

Accordingly, it is aimed to enhance a degree of freedom of a path of a wiring member to be connected to an inverter located on a wheel side.

### Means to Solve the Problem

The present disclosure is directed to a wiring member routing structure with an in-wheel motor unit including an in-wheel motor, an inverter to be connected to the in-wheel motor and a casing for accommodating the in-wheel motor and the inverter, and a wiring member for connecting the inverter and a vehicle body-side device, an end part to be connected to the inverter in the wiring member serving as a first fixed part, a part of the wiring member to be fixed to a vehicle next to the end part serving as a second fixed part, and the casing including a wiring fixing portion, the second fixed part being fixed to the wiring fixing portion.

### Effect of the Invention

According to the present disclosure, it is possible to enhance a degree of freedom of a path of a wiring member to be connected to an inverter located on a wheel side.

### BRIEF DESCRIPTION OF THE DRAWINGS

FIG. 1 is a schematic section showing a wiring member routing structure according to one embodiment.

FIG. 2 is a front view showing a casing in an in-wheel motor unit.

FIG. 3 is a section along III-III of FIG. 2.

FIG. 4 is an enlarged view of a region A of FIG. 3.

FIG. 5 is an exploded front view showing a casing according to a modification.

### DETAILED DESCRIPTION TO EXECUTE THE INVENTION

### Description of Embodiments of Present Disclosure

First, embodiments of the present disclosure are described.

The wiring member routing structure of the present disclosure is as follows.

(1) The wiring member routing structure is provided with an in-wheel motor unit including an in-wheel motor, an inverter to be connected to the in-wheel motor and a casing for accommodating the in-wheel motor and the inverter, and a wiring member for connecting the inverter and a vehicle body-side device, an end part to be connected to the inverter in the wiring member serving as a first fixed part, a part of the wiring member to be fixed to a vehicle next to the end part serving as a second fixed part, and the casing including a wiring fixing portion, the second fixed part being fixed to the wiring fixing portion. The second fixed part needs not be fixed to a component arranged around the in-wheel motor unit by being fixed to the wiring fixing portion of the casing. In this way, it is possible to enhance a degree of freedom of a path of the wiring member to be connected to the inverter located on a wheel side.

(2) In the wiring member routing structure of (1), the casing may be formed with a recess, the first fixed part may be fixed at a position of a bottom part of the recess, and the second fixed part may be fixed to a part forming an opening of the recess, out of the casing. In this way, a linear transmission member can be fixed between the first and second fixed parts while being bent as little as possible.

(3) In the wiring member routing structure of (2), the casing may include a heat dissipation fin, and at least a part of the heat dissipation fin may be used as the wiring fixing portion. In this way, the recess can be provided, utilizing a space where the heat dissipation fin is provided.

(4) The wiring member routing structure of (2) or (3) may be further provided with a lid member for covering the opening by being provided around the wiring member at the second fixed part. In this way, the second fixed part can be easily mounted on the casing.

(5) In the wiring member routing structure of (4), the lid member may include a body and an outer peripheral portion around the body, the body may be made of a resilient material, the wiring member may be passed through a hole formed in the body, and the outer peripheral portion may include a screw-shaped portion formed into a screw shape by a material higher in rigidity than the resilient material. Since the body is made of the resilient material, the body can be held in close contact with the wiring member and the rattling of the wiring member can be suppressed. Further, the lid member is easily mounted on the casing by the outer peripheral portion formed into a screw shape.

(6) In the wiring member routing structure of (5), the body may be held in close contact with the outer peripheral portion, the wiring member and the casing. In this way, a simple water sealing structure for sealing the inside of the recess against water is provided.

(7) In the wiring member routing structure of (6), the body may be provided with a first lip, a second lip and a third lip, the first lip may be provided on a part to be held in contact with the casing, out of the body, the second lip may be provided on a part to be held in contact with the outer peripheral portion, out of the body, and the third lip may be provided on a part to be held in contact with the wiring member, out of the body. In this way, a water sealing property inside the recess is enhanced.

(8) In the wiring member routing structure of any one of (1) to (7), the wiring member may include a plurality of linear transmission members and a sheath for covering the plurality of linear transmission members, and an end part of the sheath may be located between the first fixed part and the second fixed part. In this way, the plurality of linear transmission members are easily handled in mounting the second fixed part on the casing.

### Details of Embodiment of Present Disclosure

A specific example of a wiring member routing structure of the present disclosure is described below with reference to the drawings. Note that the present disclosure is not limited to these illustrations, but is represented by claims and intended to include all changes in the scope of claims and in the meaning and scope of equivalents.

### Embodiment

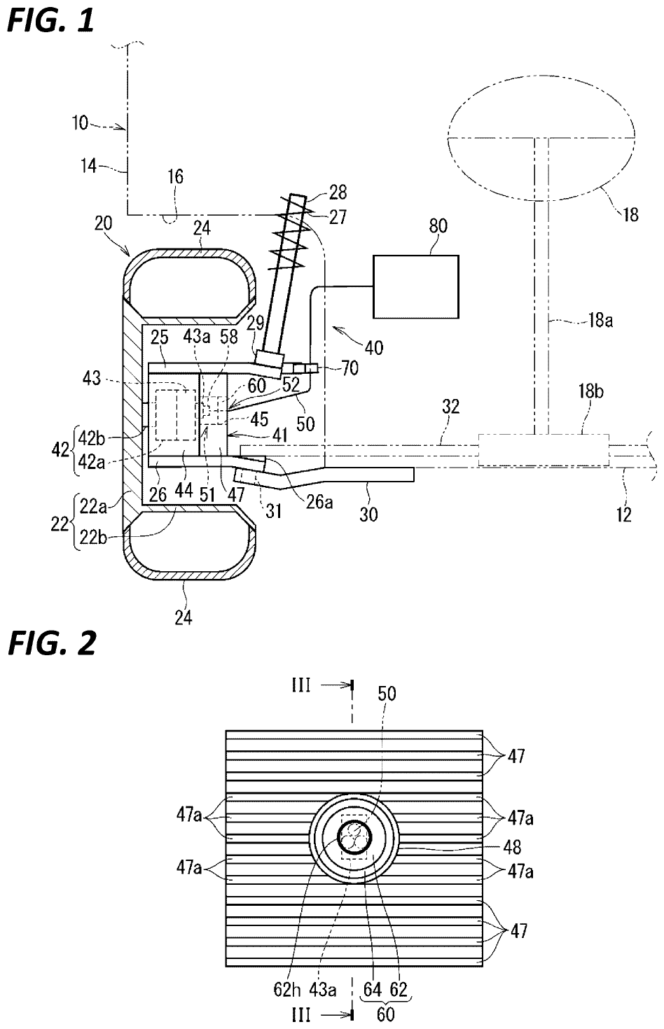

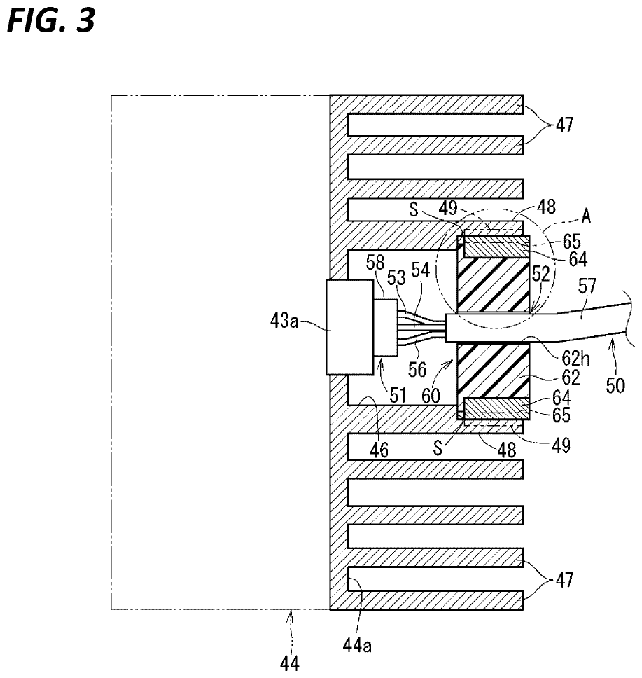

A wiring member routing structure according to one embodiment is described below. FIG. 1 is a schematic section showing a wiring member routing structure 40 according to the embodiment. FIG. 1 is a schematic section in a plane orthogonal to a front-rear direction of a vehicle body 10 and passing through a center axis of a wheel 20. In FIG. 1, the wheel 20 is shown in section. FIG. 2 is a front view showing a casing 44 in an in-wheel motor unit 41. FIG. 2 is a view of the vehicle body 10 when viewed from a lateral direction. FIG. 3 is a section along III-III of FIG. 2. In FIG. 3, a part of the casing 44 and a lid member 60 are shown in section.

### <Wiring Member Routing Structure>

The wiring member routing structure 40 is provided with the in-wheel motor unit 41 and a wiring member 50. The wiring member 50 is a member for wiring for supplying power to the in-wheel motor unit 41. Here, an in-wheel motor 42 and an inverter 43 are incorporated into the in-wheel motor unit 41, and the wiring member 50 connects the inverter 43 and a vehicle body-side device 80. The wiring member 50 is routed along a path connecting the inverter 43 and the vehicle body-side device 80.

### <Concerning Application Target of Wiring Member Routing Structure>

For the convenience of description, the configuration of a target part, to which the wiring member routing structure 40 is applied, is described.

The wiring member routing structure 40 is applied to a suspension in a vehicle. The vehicle body 10, in which a part of the wiring member 50 is routed, is a body of an automotive vehicle around the wheel 20. In FIG. 1, a part of the vehicle body 10 around the front wheel 20 is shown. In FIG. 1, the wheel 20 is shown to be steered by a steering operation. The wiring member 50 may be for a wheel not steered by the steering operation. Further, the wheel 20 may be a front wheel or a rear wheel.

The vehicle body 10 is provided with a floor part 12 and a body part 14. The floor part 12 is a part facing the ground. The body part 14 is provided above the floor part 12 and forms the exterior of the vehicle body 10. The vehicle body 10 may be a monocoque body, in which rigid frame and body are integrated, or may be configured such that a body is installed on a frame. Note that, in this embodiment, a travel direction when the automotive vehicle normally travels may be referred to as a forward direction and an opposite direction may be referred to as a rearward direction.

The wheel 20 is rotatably supported in the vehicle body 10. In an example shown in FIG. 1, the wheel 20 is rotatably supported in a fender apron 16. A suspension device may support the wheel 20 in any arbitrary suspension method such as an independent suspension method. In the example shown in FIG. 1, the wheel 20 is shown to be supported by a damper 28 and a lower arm 30. The suspension device shown in FIG. 1 is an example of a strut-type suspension device.

The wheel 20 includes a disk wheel 22 and a tire 24. The disk wheel 22 is made of metal such as iron or aluminum. The disk wheel 22 includes a disk portion 22a and a tire mounting portion 22b.

The disk portion 22a is formed into a disk shape. The disk portion 22a is, for example, fixed to an unillustrated wheel hub. The wheel hub is rotatably supported by knuckle portions 25, 26. The knuckle portions 25, 26 are supported on the vehicle body 10 via the damper 28 and the lower arm 30.

The tire mounting portion 22b is an annular part projecting inward in a vehicle width direction from the surrounding of the disk portion 22a. Annular rims project on both side edges of the tire mounting portion 22b. The tire 24 made of a resilient material such as rubber is mounted on the outer periphery of the tire mounting portion 22b.

In the example shown in FIG. 1, an upper knuckle portion 25 and a lower knuckle portion 26 are provided as the knuckle portions 25, 26.

The upper knuckle portion 25 extends inward in the vehicle width direction from the wheel hub above an axis of rotation of the wheel 20. A spring 27 and the damper 28 are provided between the upper knuckle portion 25 and the vehicle body 10. More specifically, an upper end part of the damper 28 is supported on the vehicle body 10 above the wheel 20. The upper knuckle portion 25 is rotatably supported on a lower end part of the damper 28 via a bearing portion 29.

The lower knuckle portion 26 extends inward in the vehicle width direction from the wheel hub below the axis of rotation of the wheel 20. The lower knuckle portion 26 is rotatably supported by the lower arm 30. Further, an arm portion 26a for receiving a steering force projects from the lower knuckle portion 26.

The lower arm 30 is a member made of metal or the like. A base end part of the lower arm 30 is supported swingably with respect to the floor part 12 at a position inward of the wheel 20 in the vehicle width direction. An axis serving as a center when the base end part of the lower arm 30 swings extends along the front-rear direction of the vehicle body 10. The base end part of the lower arm 30 may be supported swingably with respect to the floor part 12 obliquely in front of, inside, obliquely behind or behind the wheel 20. In these cases, an axis of rotation when the lower arm 30 swings may be along a lateral direction of the vehicle body 10, may be along the front-rear direction or may be along a direction oblique to both the lateral direction and front-rear direction.

A tip part of the lower arm 30 extends from the floor part 12 toward the inside of the fender apron 16 (outward in the vehicle width direction here). A bearing portion 31 is provided on the tip part of the lower arm 30. The lower knuckle portion 26 is rotatably supported on the tip part of the lower arm 30 via the bearing portion 31. An axis of rotation by the bearing portion 31 is a steering rotation center axis of the wheel 20 in the fender apron 16.

As described above, since the base end part of the lower arm 30 is supported swingably with respect to the floor part 12, the lower arm 30 supports the wheel 20 movably in the vertical direction in the fender apron 16. The damper 28 is interposed between the upper knuckle portion 25 and the vehicle body 10 with a moving direction of the wheel 20 restricted by the lower arm 30. An impact caused by an unevenness road surface during travel is absorbed by this damper 28 and the spring 27 externally mounted on the damper 28.

A tie rod 32 is coupled to a tip part of the arm portion 26a. If a steering wheel 18 is turned by a steering operation by a driver, that rotational motion is transmitted as a movement in the vehicle width direction to the tie rod 32 via a steering shaft 18a and a transmission mechanism 18b such as a rack and pinion mechanism. If the tie rod 32 moves in the vehicle width direction, the lower knuckle portion 26 can rotate about the axis of rotation of the bearing portion 31. In this way, the wheel 20 can turn about the steering rotation center axis by the steering operation. By the turning of the wheel 20 about the steering rotation center axis, an advancing direction of the vehicle body 10 is changed.

Hereinafter, each part in the wiring member routing structure 40 is described in detail.

### <In-Wheel Motor Unit>

The in-wheel motor unit 41 includes the in-wheel motor 42, the inverter 43 and the casing 44. The in-wheel motor unit 41 is incorporated into the wheel 20.

The in-wheel motor 42 is a travel motor for rotating the wheel 20. The in-wheel motor 42 includes a motor body 42a and a motor shaft 42b. The motor body 42a is, for example, a three-phase induction motor. The motor body 42a may be a motor other than the three-phase induction motor. The motor shaft 42b is rotated and driven by the motor body 42a. The wheel hub is mounted on the motor shaft 42b. The motor shaft 42b and the wheel hub may be directly coupled or may be mounted via a transmission mechanism or a speed reduction mechanism such as gears. By the rotation of the wheel hub according to the rotation of the motor shaft 42b, the disk portion 22a fixed to the wheel hub also rotates, with the result that the wheel 20 rotates.

The inverter 43 converts direct-current power into alternating-current power and supplies the alternating-current power to the in-wheel motor 42. Such alternating-current power is, for example, three-phase alternating-current power of U-phase, V-phase and W-phase. The alternating-current power may be single-phase alternating-current power or multi-phase alternating-current power with more than three phases. The inverter 43 is electrically connected to the in-wheel motor 42. The in-wheel motor 42 and the inverter 43 may be connected via an alternating-current wiring member different from the wiring member 50. Alternating-current power for driving the in-wheel motor 42 flows in this alternating-current wiring member. Such an alternating-current wiring member connects the in-wheel motor 42 and the inverter 43 in the in-wheel motor unit 41. Thus, normally, the alternating-current wiring member is shorter than the wiring member 50 connecting the inverter 43 in the in-wheel motor unit 41 and the vehicle body-side device 80. Such an alternating-current wiring member may include, for example, a coated wire having a stranded core wire and be bendable. Further, such an alternating-current wiring member may include a metal plate called a busbar or the like and be hard to bend. Further, terminals of the in-wheel motor 42 and the inverter 43 may be, for example, directly connected without via an alternating-current wiring member such as a coated wire or a busbar.

The inverter 43 is provided with a wiring connecting portion 43a. The wiring connecting portion 43a is connected to the wiring member 50. Here, the wiring connecting portion 43a is a connector 43a. The connector 43a includes, for example, a terminal extending from a circuit of the motor body 42a and a housing for accommodating the terminal. The wiring connecting portion 43a needs not be the connector 43a. For example, a terminal block provided with a bolt fixing portion may be a wiring connecting portion. The wiring connecting portion 43a is exposed to outside on one side surface 44a of the casing 44.

The casing 44 accommodates the in-wheel motor 42 and the inverter 43. The casing 44 includes an in-wheel motor accommodating portion for accommodating the in-wheel motor 42 and an inverter accommodating portion for accommodating the inverter 43. A positional relationship of the in-wheel motor 42 and the inverter 43 is not particularly limited and can be set as appropriate. For example, in the example shown in FIG. 1, the in-wheel motor 42 and the inverter 43 are arranged in a direction parallel to an axial direction of the wheel 20. The in-wheel motor 42 and the inverter 43 may be arranged in a direction intersecting the axial direction of the wheel 20. The casing 44 is fixed to the knuckle portions 25, 26 rotatably supporting the wheel hub. In the example shown in FIG. 1, the casing 44 is provided between the upper and lower knuckle portions 25, 26.

The casing 44 is made of metal, resin or the like. The casing 44 may be composed of one component or may be configured by combining a plurality of components. For example, the in-wheel motor accommodating portion and the inverter accommodating portion may be integrally molded as one component. Further, for example, the in-wheel motor accommodating portion and the inverter accommodating portion may be separately formed as separate components. The in-wheel motor accommodating portion and the inverter accommodating portion formed as bodies separate from each other may or may not be united in a state assembled with the vehicle. If the in-wheel motor accommodating portion and the inverter accommodating portion are not united, each of the in-wheel motor accommodating portion and the inverter accommodating portion may be fixed to the knuckle portion 25, 26 or the like.

The casing 44 is provided with a wiring fixing portion 45. In the casing 44, a location where the wiring fixing portion 45 is provided is not particularly limited and can be set as appropriate. For example, the wiring fixing portion 45 may be provided in the in-wheel motor accommodating portion or in the inverter accommodating portion. Further, for example, the wiring fixing portion 45 may be provided in a location different from the in-wheel motor accommodating portion and the inverter accommodating portion in the casing 44. Here, the casing 44 is formed with a recess 46. The wiring fixing portion 45 is provided in an opening of the recess 46. The wiring connecting portion 43a is located on a bottom part of the recess 46. The casing 44 includes heat dissipation fins 47. At least some of the heat dissipation fins 47 are used as the wiring fixing portion 45.

The heat dissipation fins 47 are provided on the side surface 44a where the wiring connecting portion 43a is exposed in the casing 44. The heat dissipation fins 47 are in the form of plates projecting outward from the side surface 44a. In the example shown in FIG. 1, the side surface 44a is facing inward in the vehicle width direction. The side surface 44a may be facing in a direction other than this. The wiring connecting portion 43a is exposed to outside through a hole formed in the side surface 44a. In the example shown in FIG. 1, the wiring connecting portion 43a projects further outward than the side surface 44a. The wiring connecting portion 43a may not project further outward than the side surface 44a.

Here, a plurality of the heat dissipation fins 47 are provided in parallel to each other. Some heat dissipation fins 47a are interrupted in an intermediate region. This region where the heat dissipation fins 47 are interrupted serves as the recess 46. That is, the recess 46 is a part surrounded by the heat dissipation fins 47. Here, a boss 48 is provided in the part where the heat dissipation fins 47 are interrupted.

The boss 48 is formed into a hollow cylindrical shape. The boss 48 is provided to surround the wiring connecting portion 43a on the side surface 44a of the casing 44. The boss 48 may be formed into a shape other than the hollow cylindrical shape. The inside of the boss 48 serves as the recess 46. The boss 48 is a peripheral wall of the recess 46. The peripheral wall 48 is formed into an annular shape. The peripheral wall 48 is provided with a screw-shaped portion 49. Here, the screw-shaped portion 49 is provided in the inner surface of an opening of the peripheral wall 48.

### <Wiring Member>

The wiring member 50 includes at least one linear transmission member for transmitting electricity or light. The linear transmission member is, for example, a wire or an optical fiber cable. Here, the wiring member 50 includes wires for supplying power to the in-wheel motor 42. FIG. 3 shows an example in which the wiring member 50 includes three wires 53, 54 and 56.

Each wire 53, 54, 56 is a coated wire including a coating around a core wire. Each wire 53, 54, 56 is a single-core wire having one electrically conductive path. Instead of a plurality of the single-core wires, a cable in which a plurality of core wires are collected into one by a coating formed by extrusion molding may be adopted. The wires 53, 54 are, for example, power supply wires for supplying direct currents to the in-wheel motor 42. The wire 56 is, for example, a signal wire for transmitting a signal. The wire 56 is a signal wire for sensor or control. The wiring member 50 may include an optical fiber cable instead of or in addition to the wires 53, 54 and 56. The plurality of wires 53, 54 and 56 are collected by a sheath 57. For example, the sheath 57 is formed around the plurality of wires 53, 54 and 56 by extrusion molding.

In a part collected by the sheath 57, a transverse section of the wiring member 50 may have any outer shape. FIG. 3 shows an example in which the transverse section of the wiring member 50 has a circular outer shape. The outer shape of the transverse section of the wiring member 50 may be an elliptical shape, a rectangular shape or the like. Note that a transverse section is a cross-section in a plane orthogonal to an axis of the wiring member 50.

One end part of the wiring member 50 is connected to the vehicle body-side device 80. The one end part of the wiring member 50 may be connector-connected to the vehicle body-side device 80. The wiring member 50 may be directly pulled out from the vehicle body-side device 80. The one end part of the wiring member 50 may be connected to the vehicle body-side device 80 via another wiring member. Such a vehicle body-side device 80 is assumed to be a drive unit for driving the in-wheel motor 42. For example, if the in-wheel motor 42 is a three-phase induction motor and the inverter 43 feeds alternating-current power such as three-phase alternating-current power with U-phase, V-phase and W-phase for driving the in-wheel motor 42 to the in-wheel motor 42, the vehicle body-side device 80 is assumed to be a battery, a DC/DC converter or the like for feeding direct-current power to the inverter 43. The DC/DC converter is a device for changing a voltage of the direct-current power from the battery and, for example, boosts the direct-current power form the battery and supplies the boosted power to the inverter 43. Note that the DC/DC converter may be omitted.

The other end part of the wiring member 50 is connected to the inverter 43. A connector 58 is provided on the other end part of the wiring member 50. End parts of the wires 53, 54 and 56 are accommodated in a housing of the connector 58. The wiring member 50 and the inverter 43 are connected via the connectors 58, 43a. The wiring member 50 and the inverter 43 may be directly connected without via the connectors 58, 43a. At the other end part of the wiring member 50, the plurality of wires 53, 54 and 56 may be branched and respectively connected to different locations.

A path of the wiring member 50 from the vehicle body-side device 80 toward the inverter 43 can be set as appropriate. For example, in the example shown in FIG. 1, the path of the wiring member 50 is set as follows. The wiring member 50 extends from the vehicle body-side device 80 in the vehicle body 10, passes through the fender apron 16 and is introduced into the inside of the fender apron 16. In the fender apron 16, the wiring member 50 is introduced toward the in-wheel motor unit 41 by way of a side lateral to the damper 28, a tip part of the upper knuckle portion 25, between the upper and lower knuckle portions 25, 26 and the like. In the in-wheel motor unit 41, the wiring member 50 extends from the opening toward the bottom part of the recess 46 of the casing 44 and is connected to the wiring connecting portion 43a of the inverter 43 at a position of the bottom part.

The end part connected and fixed to the inverter 43 in the wiring member 51 serves as a first fixed part 51. The first fixed part 51 is fixed to the wiring connecting portion 43a. The first fixed part 51 is fixed at the position of the bottom part of the recess 46. In the first fixed part 51, the plurality of wires 53, 54 and 56 extend from an end part of the sheath 57 and are loosened.

Further, a part to be fixed to the vehicle next to the end part connected to the inverter 43 in the wiring member 50 serves as a second fixed part 52. The second fixed part 52 is fixed to the wiring fixing portion 45. The second fixed part 52 is fixed to a part forming the opening of the recess 46, out of the casing 44. In the second fixed part 52, the plurality of wires 53, 54 and 56 are collected by the sheath 57. Therefore, the end part of the sheath 57 is located between the first and second fixed parts 51, 52.

The wiring member 50 extends along the casing 44 between the first and second fixed parts 51, 52. The wiring member 50 extends toward the vehicle body away from the casing 44 from the second fixed part 52. In this case, one end part of a part extending along the casing 44, out of the wiring member 50, serves as the first fixed part 51, and the other end part serves as the second fixed part 52. Note that the part of the wiring member 50 extending along the casing 44 is a part extending inside the casing 44 and extending along the surface of the casing 44.

The second fixed part 52 is fixed to the peripheral wall 48 of the recess 46 via a lid member 60. Accordingly, the wiring member routing structure 40 is further provided with the lid member 60. Further, a part closer to the vehicle body 10 than the second fixed part 52, out of the wiring member 50, in the fender apron 16 is supported by a supporting member 70. Accordingly, the wiring member routing structure 40 is further provided with the supporting member 70 here.

### <Lid Member>

The lid member 60 is provided around the wiring member 50 in the second fixed part 52. The lid member 60 covers the opening of the recess 46. Here, the lid member 60 is fit to an inner peripheral side of the peripheral wall 48 in the opening of the recess 46. The lid member 60 may not be fit to the inner peripheral side of the peripheral wall 48. For example, a lid member may be located outside the end surface of the peripheral wall 48 and close the opening of the recess 46. Further, for example, a projecting portion projecting in the axial direction may be provided on the outer edge of the lid member, and the peripheral wall 48 may be fit to an inner peripheral side of this projecting portion. The lid member 60 includes a body 62 and an outer peripheral portion 64.

The body 62 is made of a resilient material. The body 62 may have any shape. Here, the body 62 is formed to have a circular outer shape. The outer shape of the body 62 may be formed into a shape corresponding to a transverse sectional shape of the recess 46. The body 62 is formed with a hole 62h.

The hole 62h penetrates through the body 62. The hole 62h penetrates through a surface of the body 62 facing the bottom part of the recess 46 and a surface opposite to this surface. The wiring member 50 passes through the hole 62h and extends from one side toward the other side of the lid member 60. The hole 62h may have any shape. The hole 62h may be formed into a shape corresponding to a transverse sectional shape of the second fixed part 52, out of the wiring member 50. Here, a part of the wiring member 50 provided with the sheath 57 is passed through the hole 62h. Since the sheath 57 has the circular outer shape, the hole 62h is formed into a circular shape here.

Since the plurality of wires 53, 54 and 56 are collected into one by the sheath 57, there is only one hole 62h. Unless the plurality of wires 53, 54 and 56 are collected into one, there may be one hole 62h or a plurality of holes 62h. If there are a plurality of the holes 62h, the arrangement of the plurality of holes 62h and the arrangement of the plurality of wires 53, 54 and 56 passed through the plurality of holes 62h may correspond to the arrangement of the plurality of wires 53, 54 and 56 in the connector 58.

The hole 62h may have any size before the wiring member 50 is passed. The size of the hole 62h before the wiring member 50 is passed may be the same as or slightly smaller than the size of the wiring member 50 (here, the size of the sheath 57). In this case, when the wiring member 50 is passed, the hole 62h may be expanded. The size of the hole 62h before the wiring member 50 is passed may be slightly larger than the size of the wiring member 50 (here, the size of the sheath 57). A water sealant may be provided between the hole 62h and the wiring member 50. The hole 62h may have any length (thickness of the body 62). In terms of passing the wiring member 50 through the hole 62h, the hole 62h is better to be as short as possible. In terms of holding the wiring member 50 by the hole 62h, the hole 62h is better to have a length capable of holding the wiring member 50.

The hole 62h may be provided at any position in the body 62. The hole 62 may be formed at a position corresponding to a position coaxial with the wiring connecting portion 43a. The position coaxial with the wiring connecting portion 43a is a position where the wiring connecting portion 43a and the hole 62h overlap in a front view of the casing 44 as shown in FIG. 2. In this way, the wiring member 50 can extend from the first fixed part 51 toward the second fixed part 52 while being bent as little as possible.

The outer peripheral portion 64 is a part provided around the body 62. The outer peripheral portion 64 includes a screw-shaped portion 65. The screw-shaped portion 65 is made of a material higher in rigidity than the resilient material. Here, the screw-shaped portion 65 is provided in the outward facing surface of the outer peripheral portion 64. The screw-shaped portion 65 is fastened to the screw-shaped portion 49 of the peripheral wall 48. The screw-shaped portions 49, 65 are formed into matching shapes. The outer peripheral portion 64 includes a part projecting along an axial direction of the lid member 60 and a screw-shaped portion may be provided in the inward facing surface of that projecting part.

The screw-shaped portion 65 in the outer peripheral portion 64 and the body 62 are free to rotate. In this way, when the screw-shaped portions 49, 65 are threadably fastened or the threadably fastened screw-shaped portions 49, 65 are released, the rotation of the wiring member 50 passed through the body 62 is suppressed. For example, the outer peripheral portion 64 may include a bearing for rotatably coupling the screw-shaped portion 65 and the body 62. The bearing may be provided on an outer peripheral side of the body 62, and the screw-shaped portion 65 may be provided on an outer peripheral side of the bearing.

With the screw-shaped portions 49, 65 threadably fastened, the rotation of the body 62 with respect to the screw-shaped portion 65 may be suppressed. In this way, the rotation of the wiring member 50 passed through the body 62 is suppressed with the screw-shaped portions 49, 65 threadably fastened. For example, a part of the peripheral wall 48 closer to the bottom part than the screw-shaped portion 49 projects toward an inner peripheral side to provide a step S. With the screw-shaped portions 49, 65 threadably fastened, a step part of the peripheral wall 48 and the outer edge of the body 62 are held in close contact. In this way, with the screw-shaped portions 49, 65 threadably fastened, the rotation of the body 62 with respect to the screw-shaped portion 65 is suppressed by friction between the peripheral wall 48 and the body 62.

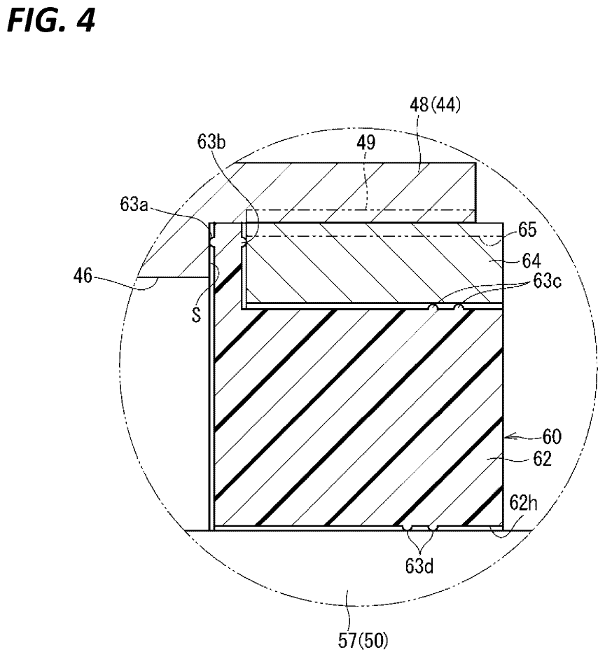

Here, the inside of the recess 46 is sealed against water by the lid member 60. This is described in detail with reference to FIG. 4. FIG. 4 is an enlarged view of a region A of FIG. 3.

Specifically, the body 62 in the lid member 60 is held in close contact with each of the casing 44, the outer peripheral portion 64 and the wiring member 50. In this way, water intrusion between the body 62 and the casing 55 and between the outer peripheral portion 64 and the wiring member 50 is suppressed. Here, the body 62 is held in close contact with the outer peripheral portion 64 and the wiring member 50 in a radial direction of the wiring member 50, and held in close contact with the outer peripheral portion 64 and the casing 44 in a longitudinal direction of the wiring member 50. At this time, the body 62 is provided with lips on parts to be held in contact with each of the casing 44, the outer peripheral portion 64 and the wiring member 50. A first lip 63a, second lips 63b, 63c and third lips 63d are provided as such lips in an example shown in FIG. 4.

The first lip 63a is provided on the part of the body 62 to be held in contact with the casing 44. More particularly, the step S of the peripheral wall 48, out of the casing 44, is formed into an annular shape. An outer peripheral edge part of an axially facing end surface of the body 62 is in contact with the step S. The first lip 63a is annularly provided on this outer peripheral edge part in the body 62. The first lip 63a is arranged side by side with the step S in the axial direction. The annular first lip 63a is in contact with the step S over an entire periphery. The first lip 63a may be sandwiched and pressed in the axial direction by the step S and the outer peripheral portion 64 with the screw-shaped portions 49, 65 threadably fastened.

The second lips 63b, 63c are provided on a part of the body 62 to be held in contact with the outer peripheral portion 64. More particularly, the second lip 63b is annularly provided on a surface of the body 62 on the back of the end surface provided with the first lip 63a. In the example shown in FIG. 4, the second lip 63b is provided right on the back of the first lip 63a, but the first and second lips 63a, 63b may be separately provided inside and outside along the radial direction. The second lip 63b is arranged side by side with the outer peripheral portion 64 in the axial direction. The annular second lip 63b is in contact with an annular end surface of the outer peripheral portion 64 over an entire periphery. The second lip 63b may be sandwiched and pressed in the axial direction by the step S and the outer peripheral portion 64 with the screw-shaped portions 49, 65 threadably fastened.

Further, the second lips 63c are annularly provided on the outer peripheral surface of the body 62 facing the inner peripheral surface of the outer peripheral portion 64 over an entire periphery. In the example shown in FIG. 4, two second lips 63c are provided apart from each other in the axial direction on the outer peripheral surface of the body 62. The second lips 63c are arranged side by side with the outer peripheral portion 64 in the radial direction. The annular second lips 63c are in contact with the inner peripheral surface of the outer peripheral portion 64 over the entire periphery.

The third lips 63d are provided on a part of the body 62 to be held in contact with the wiring member 50. More particularly, the third lips 63d are annularly provided on the inner peripheral surface of the hole 62h of the body 62 over an entire periphery. In the example shown in FIG. 4, two third lips 63d are provided apart from each other in the axial direction on the inner peripheral surface of the hole 62h. The third lips 63d are arranged side by side with the sheath 57 of the wiring member 50 in the radial direction. The annular third lips 63d are in contact with the outer peripheral surface of the sheath 57 over the entire periphery.

Of course, the inside of the recess 46 needs not be sealed against water by the lid member 60. Further, even if the inside of the recess 46 is sealed against water by the lid member 60, a structure therefor is not limited to the one described above. For example, in the example shown in FIG. 4, one each of the first lip 63a and the second lip 63b is provided, and two each of the second lips 63c and the third lips 63d are provided. However, the numbers of the respective lips are not limited to those and can be set as appropriate. Further, although two types of the second lips 63b, 63c are provided in the example shown in FIG. 4, either the second lip 63b or the second lips 63c may be omitted. Further, although the lid member 60 is mounted on the casing 44 with the spring-shaped portions 49, 65 threadably fastened in the example shown in FIG. 4, a lid member may be press-fit into the casing 44.

Further, the lid member 60 may have an oil sealing property. For example, oil may be provided inside the recess 46 and the leakage of the oil from the recess 46 may be suppressed by the lid member 60. The configuration of the lid member having such an oil sealing property is not particularly limited, but the lid member may include, for example, a biasing member for biasing the third lips 63d toward the wiring member 50 outside the third lips 63d. In this case, the body 62 may be provided with a mounting portion, into which the biasing member is mounted. Such a biasing member may be, for example, an annular spring member such as a coil spring.

The lid member 60 is a member formed separately from the wiring member 50 and mounted on the wiring member 50 later.

### (Supporting Member 70)

In the example shown in FIG. 1, the supporting member 70 is mounted on the wiring member 50. The supporting member 70 is supported on the upper knuckle portion 25. For example, the supporting member 70 is a bracket. The bracket is screwed to a mounting target.

Of course, the supporting member 70 only has to support the wiring member 50 between the second fixed part 52 and the vehicle body-side device 80 in the above routing form and a structure therefor is not particularly limited. The supporting member may be a single supporting member or may include a plurality of supporting parts. Further, a supporting member may be supported on the side of the vehicle body 10 or on the side of the wheel 20. Here, that the supporting member is supported on the side of the vehicle body 10 means that the supporting member is supported on a part, which does not turn even if the wheel 20 turns about the steering rotation center axis. For example, the supporting member may be supported on the damper 28 or the lower arm 30 besides being supported on the vehicle body 10. Further, that the supporting member 70 is supported on the side of the wheel 20 means that the supporting member 70 is supported on a part, which turns, following the wheel 20, if the wheel 20 turns about the steering rotation center axis. For example, the supporting member 70 may be supported on the upper knuckle portion 25 or the lower knuckle portion 26.

One or both of the lid member 60 and the supporting member 70 may be mounted on the wiring member 50 in advance before being mounted on the vehicle. An assembly obtained by mounting one or both of the lid member 60 and the supporting member 70 on the wiring member 50 in advance can also be considered as a wiring module. In the wiring module in which both the lid member 60 and the supporting member 70 are mounted on the wiring member 50 in advance, the lid member 60 and the supporting member 70 are provided in this order from the end part to be connected to the inverter 43.

### Effects and the Like of Embodiment

According to the wiring member routing structure 40 configured as described above, the second fixed part 52 needs not be fixed to a component arranged around the in-wheel motor unit 41 by being fixed to the wiring fixing portion 45 of the casing 44. In this way, the paths of the wires 53, 54 and 56 to be connected to the in-wheel motor unit 41 can have a higher degree of freedom. More particularly, to reduce a force applied to the end part of the wiring member 50, the position of the fixed part next to the end part may be set near the end part (e.g. a position within X mm from the end part, where X is, for example, any value from 100 to 300). If the position of the fixed part next to the end part is set on a peripheral component near the inverter 43 in this range, that fixed position is limited, whereby the path of the wiring member 50 may have a reduced degree of freedom. In contrast, by fixing the second fixed part 52 to the wiring fixing portion 45 of the casing 44 here, the path to the vehicle body-side device 80 from the second fixed part 52 has a higher degree of freedom. Further, the mounted position of the supporting member 70 also has a higher degree of freedom.

Further, the first fixed part 51 is fixed at the position of the bottom part of the recess 46 and the second fixed part 52 is fixed at the position of the opening of the recess 46. In this way, the wiring member 50 can be fixed between the first and second fixed parts 51, 52 while being bent as little as possible.

Further, the casing 44 includes the heat dissipation fins 47 provided on the peripheral edge of the opening of the recess 46. In this way, the recess 46 can be provided, utilizing a space where the heat dissipation fins 47 are provided. The heat dissipation fins 47 constitute a part of the wiring fixing portion 45. The recess 46 is formed in the part of the casing 44 projecting by providing the heat dissipation fins 47. In this way, the size enlargement of the casing 44 due to the formation of the recess 46 can be suppressed.

Further, the wiring member 50 further includes the lid member 60 to be mounted into the opening of the recess 46 by being provided around the wiring member 50 at the second fixed part 52. In this way, the second fixed part 52 can be easily mounted on the casing 44 via the lid member 60.

Further, since the body 62 of the lid member 60 is made of the resilient material, the body 62 can be held in close contact with the wires 53, 54 and 56 and the rattling of the wires 53, 54 and 56 can be suppressed. Further, the lid member 60 is easily mounted on the casing 44 by the outer peripheral portion 64 of the lid member 60 formed into a screw shape.

Further, the inside of the recess 46 is sealed against water by the peripheral wall 48 of the recess 46 and the lid member 60. Specifically, the body 62 is held in close contact with each of the casing 44, the outer peripheral portion 64 and the wiring member 50. In this way, a simple water sealing structure for sealing the inside of the recess 46 against water is provided. Further, the first lip 63a, the second lips 63b, 63c and the third lips 63d are provided on the parts of the body 62 to be held in contact with each of the casing 44, the outer peripheral portion 64 and the wiring member 50. In this way, a water sealing property inside the recess 46 is enhanced.

Further, the end part of the sheath 57 is located between the first and second fixed parts 51, 52. In this way, the plurality of wires 53, 54 and 56 are easily handled in mounting the second fixed part 52 on the casing 44.

### Modification

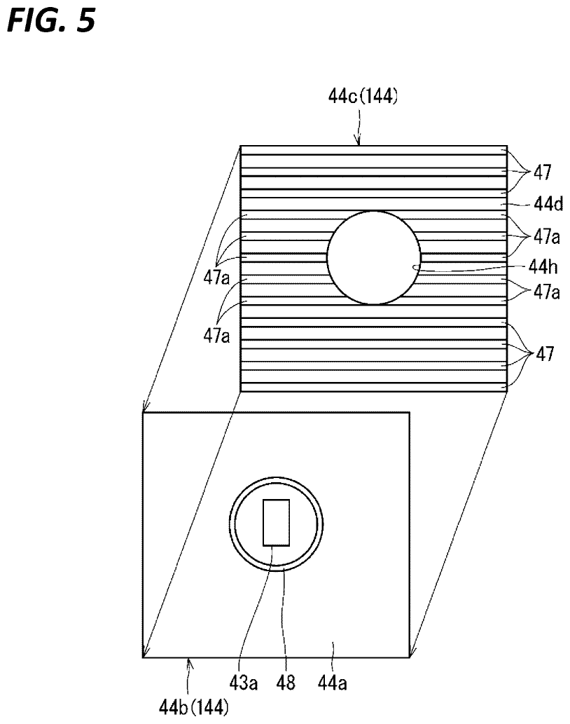

FIG. 5 is an exploded front view showing a casing 144 according to a modification.

In the casing 144, the heat dissipation fins 47 are post-fit. The casing 144 includes a casing body 44b and a heat dissipating member 44c. The casing body 44b and the heat dissipating member 44c are united into the casing 144 after being formed separately from each other. The casing body 44b and the heat dissipating member 44c are, for example, united by screwing or the like.

The casing body 44b accommodates the inverter 43. The connector 43a is provided on a side surface 44a of the casing body 44b. Here, the boss 48 is also provided on the side surface 44a of the casing body 44b. The boss 48 may be provided on the heat dissipating member 44c.

The heat dissipating member 44c includes a base plate portion 44d and a multitude of the heat dissipation fins 47 projecting from the base plate portion 44d. The heat dissipation fins 47 project from one principal surface of the base plate portion 44d. The base plate portion 44d is formed with a through hole 44h for allowing the passage of the boss 48.

The other principal surface of the base plate portion 44d faces the side surface 44a of the casing body 44b. An intervening member higher in thermal conductivity than air may be interposed between the other principal surface of the base plate portion 44d and the side surface 44a of the casing body 44b. The intervening member may be, for example, a member easily deformable into a shape corresponding to a gap between the other principal surface of the base plate portion 44d and the side surface 44a of the casing body 44b. The intervening member may be a flexible member such as a heat dissipation sheet or thermal grease or may be a member formed by curing a member flexible at least before curing.

Although the recess 46 has been described to be formed in the casing 44 thus far, this is not an essential configuration. For example, the wiring connecting portion may be located on a side surface where the heat dissipation fins are not provided in the casing. Further, the wiring member 50 may be bent and routed between the first and second fixed parts 51, 52.

Further, although the heat dissipation fins 47 have been described to be provided on the peripheral edge of the opening in the recess 46 thus far, this is not an essential configuration. The recess 46 may be formed in a part of the casing where the heat dissipation fins 47 are not provided.

Further, although the second fixed part 52 has been described to be fixed to the wiring fixing portion 45 by the lid member 60 thus far, this is not an essential configuration. For example, the second fixed part 52 may be fixed to the wiring fixing portion 45 by a component other than the lid member 60 such as a bracket. Further, the second fixed part 52 may be directly fixed to the casing 44, such as by forming the wiring fixing portion 45 into a shape capable of directly supporting the wiring member 50 such as a clip shape.

Further, although the lid member 60 has been described to include the body 62 made of the resilient material and the outer peripheral portion 64 higher in rigidity than the body 62 thus far, this is not an essential configuration. For example, in the lid member, the outer peripheral portion 64 may be omitted. In this case, the lid member may be press-fit into the opening of the recess 46. Further, for example, the lid member may be mounted into the recess 46 by a screw different from the screw-shaped portions 49, 65. At this time, a screw receiver may be provided on the outer side of the peripheral wall of the recess and a screw hole may be provided at a position corresponding to the screw receiver, out of the outer peripheral portion. Further, for example, the lid member may be an insert-molded body formed with the wiring member 50 as an insert by insert molding.

Further, although the plurality of wires 53, 54 and 56 have been described to be collected into one by the sheath 57 thus far, this is not an essential configuration. For example, the plurality of wires 53, 54 and 56 may not be collected into one. Further, for example, a member for collecting the plurality of wires 53, 54 and 56 may be a protecting member other than the sheath 57. Such a protecting member may be, for example, a corrugated tube, a helically wound adhesive tape, or a resin or metal tube. Further, the plurality of wires 53, 54 and 56 need not be collected into one entirely in a longitudinal direction thereof. For example, the sheath 57 may be omitted and the plurality of wires 53, 54 and 56 may be collected into one by the lid member 60 for supporting the wiring member 50 at the fixed position, a bracket or the like. The bracket here may be the supporting member 70.

Further, the wiring member 50 may include wires other than the wires 53, 54 and 56 for the in-wheel motor unit 41. Such wires are connected to peripheral devices arranged around the in-wheel motor unit 41. A sensor, an electric brake and the like can be, for example, assumed as such peripheral devices. For example, the sensor may be a sensor for detecting a rotation speed of the wheel 20 or a temperature sensor for detecting a temperature of the in-wheel motor 42, the inverter 43 or the like. The electric brake may be an electric parking brake used when the automotive vehicle is parked or stopped or a brake used during the travel of the automotive vehicle.

Connecting parts of these peripheral devices and the wires for peripheral device may be provided at the same position as the connecting part of the wires 53, 54, and 56 and the inverter 43 or may be provided at different positions. If the connecting parts of the peripheral devices and the wires for peripheral device are provided at positions different from the connecting part of the wires 53, 54 and 56 and the inverter 43, the wires 53, 54 and 56 and the wires for peripheral device may be branched on a side closer to the vehicle body-side device 80 than the lid member 60.

A vehicle body-side device to be connected to the peripheral device by the wire for peripheral device may be a device for transmitting and receiving a signal to and from the peripheral device or supplying power to the peripheral device. For example, the vehicle body-side device may have a function as an ECU (Electronic Control Unit) for receiving a signal from a sensor and controlling the electric brake. The vehicle body-side device may be provided in the vehicle body 10 or outside the vehicle body 10.

Note that the respective configurations described in the above embodiment and the respective modifications can be combined as appropriate without contradicting each other.

### LIST OF REFERENCE NUMERALS

10 vehicle body
12 floor part
14 body part
16 fender apron
18 steering wheel
18a steering shaft
18b transmission mechanism
20 wheel
22 disk wheel
22a disk portion
22b tire mounting portion
24 tire
25 upper knuckle portion
26 lower knuckle portion
26a arm portion
27 spring
28 damper
29 bearing portion
30 lower arm
31 bearing portion
32 tie rod
40 routing structure
41 in-wheel motor unit
42 in-wheel motor
42a motor body
42b motor shaft
43 inverter
43a wiring connecting portion (connector)
44, 144 casing
44a side surface
44b casing body
44c heat dissipating member
44d base plate portion
44h through hole
45 wiring fixing portion
46 recess
47 heat dissipation fin
48 boss (peripheral wall of recess)
49 screw-shaped portion
50 wiring member
51 first fixed part
52 second fixed part
53, 54, 56 wire
57 sheath
58 connector
60 lid member
62 body
62h hole
63a first lip
63b, 63c second lip
63d third lip
64 outer peripheral portion
65 screw-shaped portion
70 supporting member
80 vehicle body-side device

1. A wiring member routing structure, comprising:
an in-wheel motor unit including an in-wheel motor, an inverter to be connected to the in-wheel motor and a casing for accommodating the in-wheel motor and the inverter; and
a wiring member for connecting the inverter and a vehicle body-side device,
an end part to be connected to the inverter in the wiring member serving as a first fixed part, a part of the wiring member to be fixed to a vehicle next to the end part serving as a second fixed part, and
the casing including a wiring fixing portion, the second fixed part being fixed to the wiring fixing portion.

2. The wiring member routing structure of claim 1, wherein the casing is formed with a recess, the first fixed part is fixed at a position of a bottom part of the recess, and the second fixed part is fixed to a part forming an opening of the recess, out of the casing.

3. The wiring member routing structure of claim 2, wherein:
the casing includes a heat dissipation fin, and
at least a part of the heat dissipation fin is used as the wiring fixing portion.

4. The wiring member routing structure of claim 2, further comprising a lid member for covering the opening by being provided around the wiring member at the second fixed part.

5. The wiring member routing structure of claim 4, wherein:
the lid member includes a body and an outer peripheral portion around the body,
the body is made of a resilient material,
the wiring member is passed through a hole formed in the body, and
the outer peripheral portion includes a screw-shaped portion formed into a screw shape by a material higher in rigidity than the resilient material.

6. The wiring member routing structure of claim 5, wherein the body is held in close contact with the outer peripheral portion, the wiring member and the casing.

7. The wiring member routing structure of claim 6, wherein:
the body is provided with a first lip, a second lip and a third lip,
the first lip is provided on a part to be held in contact with the casing, out of the body,
the second lip is provided on a part to be held in contact with the outer peripheral portion, out of the body, and
the third lip is provided on a part to be held in contact with the wiring member, out of the body.

8. The wiring member routing structure of claim 1, wherein
the wiring member includes a plurality of linear transmission members and a sheath for covering the plurality of linear transmission members, and
an end part of the sheath is located between the first fixed part and the second fixed part.
